(19) United States
(12) Patent Application Publication
(10) Pub. No.: US 2010/0183987 A1
(43) Pub. Date: Jul. 22, 2010

(54) EXPOSURE APPARATUS

(75) Inventor: Masami Yonekawa, Utsunomiya-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/305,851

(22) PCT Filed: Dec. 5, 2007
(86) PCT No.: PCT/JP2007/073888

§ 371 Date: Dec. 19, 2008

(30) Foreign Application Priority Data
Dec. 8, 2006 (JP) 2006-332172

(51) Int. Cl. G03B 27/52; G03F 7/20

(52) U.S. Cl. 430/325; 355/30

(57) ABSTRACT

An exposure apparatus for exposing a substrate to radiant energy in a vacuum is disclosed. The apparatus comprises a chamber in which the vacuum is generated, a blowing device including a supply nozzle (17a) located in the chamber and configured to blow, through said supply nozzle, a gas to an object (2) arranged in the chamber in which the vacuum is generated, and a recovery device including a recovery nozzle (17b) located in the chamber and configured to recover, through the recovery nozzle, the gas blown into the chamber through said supply nozzle, wherein the apparatus is configured so that the object moves in a direction opposite to a direction from the supply nozzle to the recover nozzle, parallel to blowing by the blowing device.

### TECHNICAL FIELD

The present invention relates to an exposure apparatus for exposing a substrate to radiant energy. The exposure apparatus according to the present invention is suitable as an exposure apparatus using, e.g., EUV (Extreme Ultra Violet) light as radiant energy.

### BACKGROUND ART

At present, the manufacture of semiconductor devices such as a DRAM and MPU are under extensive study and development, aiming at attaining devices having line widths of 50 nm or less on the design rule. A promising exposure apparatus used in this generation is an exposure apparatus (EUV exposure apparatus) using EUV light. In the EUV exposure apparatus, the optical path of EUV light is set under a vacuum environment to prevent gasses from absorbing the EUV light.

In general, a semiconductor exposure apparatus reduces and transfers a circuit pattern image drawn on a reticle (mask) onto a wafer using a projection optical system. If, for example, a particle (minute foreign substance) adheres on the circuit pattern surface of the reticle, its image is transferred at just the same position as that of each shot. This particle adhesion results in a decrease in the manufacturing yield of semiconductor devices or in a decrease in the reliability of the semiconductor devices itself.

To solve this problem, in an exposure apparatus using, e.g., a mercury lamp or excimer laser as a light source, a transparent protective film called a pellicle is formed with a spacing of several mm from the reticle to suppress any particles from directly adhering on the circuit pattern surface and their images from being transferred onto the wafer.

However, the pellicle thickness which satisfies the transmittance required for the EUV exposure apparatus is several tens of nm. Such a very thin pellicle can obtain neither a sufficient mechanical strength nor thermal resistance. For this reason, the EUV exposure apparatus can hardly prevent particle adhesion using the pellicle in practice.

Patent references 1 and 2 propose a method using a pulse laser as a means for preventing any particles from adhering on, e.g., a reticle without using the pellicle.

[Patent Reference 1] Japanese Patent Publication No. 6-95510

[Patent Reference 2] Japanese Patent Laid-Open No. 2000-88999

Unfortunately, patent reference 1 removes particles adhering on the mask by moving it to a position different from that during exposure and cleaning it. This requires much time to clean the mask, resulting in a decrease in throughput. Still worse, particles may be inevitably generated upon sliding and friction in the process of moving the cleaned mask to the exposure position, and adhere on the mask again.

Patent reference 2 introduces an inert gas into a chamber to clean the reticle. This is to use the inert gas to trap particles separated upon laser irradiation and recover them together with the gas. However, the inside of a vacuum chamber of the EUV exposure apparatus must be kept under a high vacuum ((10×10⁻³ to 10×10⁻⁵) Pa) environment. Once the gas is introduced into the chamber as described in patent reference 2, exposure becomes impossible. In this case, it takes a much time to obtain a high vacuum state again, so the effective operation rate of the apparatus significantly decreases.

If a particle is generated in the exposure apparatus under a vacuum environment, there are often no clues to where and how it is generated, and its material and diameter. Therefore, a method using only a pulse laser is expected to drastically decrease the removal rate due to adhesion of particles.

### DISCLOSURE OF INVENTION

It is an exemplary object of the present invention to reduce decreases in apparatus operation rate due to cleaning of an object.

According to a first aspect of the present invention, there is provided an exposure apparatus for exposing a substrate to radiant energy in a vacuum, the apparatus comprising a chamber in which the vacuum is generated, a blowing device including a supply nozzle located in the chamber and configured to blow, through the supply nozzle, a gas to an object arranged in the chamber in which the vacuum is generated, and a recovery device including a recovery nozzle located in the chamber and configured to recover, through the recovery nozzle, the gas blown into the chamber through the supply nozzle, wherein the apparatus is configured so that the object moves in a direction opposite to a direction from the supply nozzle to the recovery nozzle, parallel to blowing by the blowing device.

According to a second aspect of the present invention, there is provided an exposure apparatus for exposing a substrate to radiant energy in a vacuum, the apparatus comprising a chamber in which the vacuum is generated, a blowing device including a supply nozzle located in the chamber and configured to blow, through the supply nozzle, a gas to an object arranged in the chamber in which the vacuum is generated, a recovery device including a recovery nozzle located in the chamber and configured to recover, through the recovery nozzle, the gas blown into the chamber through the supply nozzle, and an irradiator configured to irradiate the object with a pulse laser light, wherein the apparatus is configured so that a region on the object, to which said blowing device blows the gas, overlaps a region on the object, which is irradiated with the pulse laser light, and gas blowing by the blowing device and pulse laser light irradiation by the irradiator are performed in synchronism with each other.

According to a third aspect of the present invention, there is provided an exposure apparatus for exposing a substrate to radiant energy in a vacuum, the apparatus comprising a chamber in which the vacuum is generated, a blowing device including a supply nozzle located in the chamber and configured to blow, through the supply nozzle, a gas to an object arranged in the chamber in which the vacuum is generated, and a recovery device including a recovery nozzle located in the chamber, and recovers, through the recovery nozzle, the gas blown into the chamber through the supply nozzle, wherein the apparatus is configured so that the blowing device blows a supersonic gas with a shock wave.

According to a fourth aspect of the present invention, there is provided an exposure apparatus for exposing a substrate to radiant energy in a vacuum, the apparatus comprising a chamber in which the vacuum is generated, a blowing device including a supply nozzle located in the chamber and configured to blow, through the supply nozzle, a gas to an object arranged in the chamber in which the vacuum is generated, and a recovery device including a recovery nozzle located in the chamber and configured to recover, through the recovery nozzle, the gas blown into the chamber through the supply nozzle, wherein the apparatus is configured so that a component of the gas blown by the blowing device is sublimated to a solid.

According to a fifth aspect of the present invention, there is provided a method of manufacturing a device, the method including: exposing a substrate to radiant energy using the above-described exposure apparatus; developing the exposed substrate; and processing the developed substrate to manufacture the device.

Further features of the present invention will become apparent from the following description of exemplary embodiments with reference to the attached drawings.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a view showing the schematic arrangement of an exposure apparatus;

FIG. 2 shows graphs indicating changes in the pressure, temperature, and saturation ratio of a gas upon adiabatic expansion;

FIG. 3 is a partially enlarged view showing a cleaning mechanism according to the first embodiment;

FIG. 4 is a view showing the positional relationship between a supply nozzle and a recovery nozzle according to the first embodiment;

FIG. 5 is a chart for explaining synchronization between a master signal and each slave signal;

FIG. 6 is a graph showing the experimental result concerning the relationship between the pulse laser irradiation count and the particle removal rate;

FIG. 7 is a view showing the relationship among the reticle position, the laser irradiation position, and the gas jet position;

FIG. 8 is a flowchart illustrating a reticle cleaning sequence;

FIG. 9 is a flowchart illustrating another reticle cleaning sequence;

FIG. 10 is a view showing a cleaning mechanism according to the second embodiment;

FIG. 11 is a view showing another cleaning mechanism according to the second embodiment;

FIG. 12 is a view showing a cleaning mechanism according to the third embodiment;

FIG. 13 is a view showing the positional relationship between a supply nozzle and a recovery nozzle according to the third embodiment;

FIG. 14 is a view showing the relationship among the wafer chuck position, the laser irradiation position, and the gas jet position;

FIG. 15 is a flowchart illustrating a wafer chuck cleaning sequence;

FIG. 16 is a view showing a cleaning mechanism according to the fourth embodiment;

FIG. 17 is a flowchart illustrating a wafer cleaning sequence;

FIGS. 18A and 18B are views for explaining the shape of a gas supply port;

FIG. 19 is a flowchart illustrating semiconductor device manufacturing processing; and

FIG. 20 is a flowchart illustrating details of the wafer process shown in FIG. 19.

### BEST MODE FOR CARRYING OUT THE INVENTION

### First Embodiment

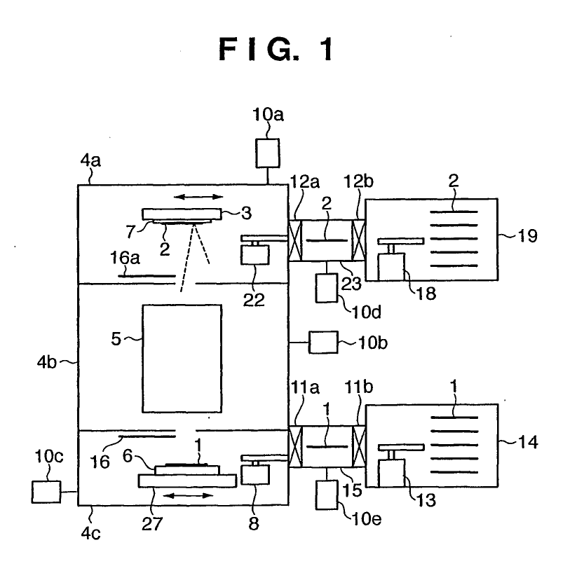

An exposure apparatus according to an embodiment of the present invention will be described with reference to the accompanying drawings. FIG. 1 is a view showing the schematic arrangement of an EUV exposure apparatus according to the first embodiment.

Referring to FIG. 1, reference numeral 1 denotes a wafer; 2, a reflecting reticle on which a circuit pattern is formed; 7, a reticle chuck for holding and fixing the reticle 2; 3, a reticle stage for coarsely and finely moving the reticle 2 in the scanning direction; 5, a projection optical system for transferring the circuit pattern formed on the reticle 2 onto the wafer 1; 6, a wafer chuck for holding and fixing the wafer 1; and 27, a wafer stage which can coarsely and finely move in six axial directions. A laser interferometer (not shown) always monitors the position of the wafer stage 27 in the X and Y directions.

The scanning operations of the reticle stage 3 and wafer stage 27 are synchronously controlled to satisfy:

Vr/Vw=β

where 1/β is the reduction magnification of the projection optical system 5, Vr is the scanning velocity of the reticle chuck 7, and Vw is the scanning velocity of the wafer stage 27.

The reticle stage 3, projection optical system 5, and wafer stage 27 are accommodated in a reticle stage space 4a, projection optical system space 4b, and wafer stage space 4c, respectively. Gate valves 16a and 16b can partition these spaces. Vacuum exhaust units 10a, 10b, and 10c are independently accommodated in the respective spaces so as to independently control their pressures. With this arrangement, exposure can be performed under a vacuum environment as high as (10×10⁻³ to 10×10⁻⁵) Pa.

Reference numeral 15 denotes a wafer load lock chamber; 8, a transport hand for loading or unloading the wafer 1 between the wafer load lock chamber 15 and the wafer stage 27; 10e, a vacuum exhaust unit for the wafer load lock chamber 15; 14, a wafer exchange room for temporarily storing the wafer 1 under an atmospheric pressure; and 13, a transport hand for loading or unloading the wafer 1 between the transport hand 8 and the wafer 1. A gate valve 11a is inserted between the wafer stage space 4c and the wafer load lock chamber 15. A gate valve 11b is inserted between the wafer load lock chamber 15 and the wafer exchange room 14.

Reference numeral 23 denotes a reticle load lock chamber; 22, a transport hand for loading or unloading the reticle 2 between the reticle load lock chamber 23 and the reticle stage 3; 10d, a vacuum exhaust unit for the reticle load lock chamber 23; 19, a reticle exchange room for temporarily storing the reticle 2 under an atmospheric pressure; and 18, a transport hand for loading or unloading the reticle 2 between the reticle load lock chamber 23 and the reticle exchange room 19. A gate valve 12a is inserted between the reticle stage space 4a and the reticle load lock chamber 23. A gate valve 12b is inserted between the reticle load lock chamber 23 and the reticle exchange room 19.

In this embodiment, three removal action forces to be described hereinafter are used simultaneously or independently to remove particles adhering on a cleaning target surface (e.g., a reticle surface).

The first cleaning action uses irradiation with a UV pulse laser. This action utilizes, e.g., a thermoelastic wave action which instantaneously occurs on a substrate upon irradiation with a pulse beam having a cycle on the order of nsec, or a photochemical action which occurs upon irradiation with light in the UV range. By combining these actions, adhering particles are removed from the substrate.

The second cleaning action uses a gas jet. This action obtains a removal effect by blowing a gas jet onto a surface, on which particles are adhering, so that a supersonic shock wave acts on them. In general, when the gas is air, the flow rate exceeds the sound velocity as the pressure ratio becomes equal to or higher than 0.528. In this embodiment, a stream that flows at a velocity exceeding the sound velocity and produces a shock wave is easily generated by blowing a gas at normal pressure under a vacuum environment.

The third cleaning action uses adiabatic expansion by blowing a gas in a vacuum. In general, the temperature of a gas drops upon its rapid adiabatic expansion. At the same time, the saturated vapor pressure of the gas drops and it condenses. If the temperature drops more extremely, the droplet becomes colder and then solidifies into fine particles. This action obtains a particle removal action by causing these solidified fine particles to physically impinge on a particle at a supersonic velocity.

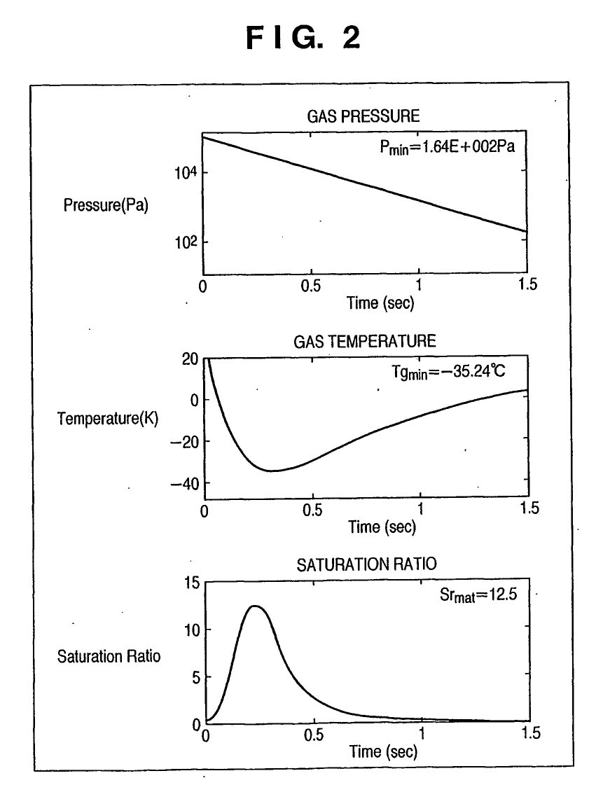

A mechanism associated with the third action will be explained using a simple model obtained by trial calculation shown in FIG. 2.

More specifically, assume a case in which air at a relative humidity of 50% (23° C.) fills a closed space with a volume of about 1 cc. The probability of water vapor condensation was simulated assuming that an ideal exhaust system with an effective exhaust velocity of 200 cc/min evacuated the space. Referring to FIG. 2, the upper stage indicates the pressure in the closed space upon adiabatic expansion. The middle stage indicates the temperature of a gas. The lower stage indicates the plots of a value Sr (to be referred to as the saturation ratio hereinafter) given by:

$$Sr = \frac{{P}_{vap}}{{P}_{sat}}$$

where Psat is the saturated water vapor pressure of the gas, and Pvap is the water vapor pressure of the gas. When the saturation ratio Sr≧1 and the gas contains a particle, the water vapor normally condenses around the particle as a nucleus (heterogeneous nucleation). Since the gas used in this embodiment contains no particle which acts as a nucleus, homogeneous nucleation occurs in which the water vapor condenses without any nucleus. The saturation ratio at this time is normally Sr≧4. As is obvious from this trial calculation, when a gas is supplied under the above-described condition, the saturation ratio readily exceeds 4 and the water vapor condenses. In addition, since the gas temperature drops to the freezing point or less, the droplet generated upon condensation further condenses into fine particles, i.e., shifts to an ice phase.

Although the case using air and water vapor has been exemplified above, the same applies to other types of gasses. When a gas is blown into a vacuum, its temperature drops upon rapid adiabatic expansion in a nozzle. The gas condensed into fine particles impinges on a particle at a supersonic velocity. This physical action removes the particle. The fine gas particles remaining after particle removal vaporize again, and are discharged outside a vacuum chamber by a vacuum pump.

According to this embodiment, it is possible to effectively remove any particles on a reticle using the above-described three particle removal action forces simultaneously or independently.

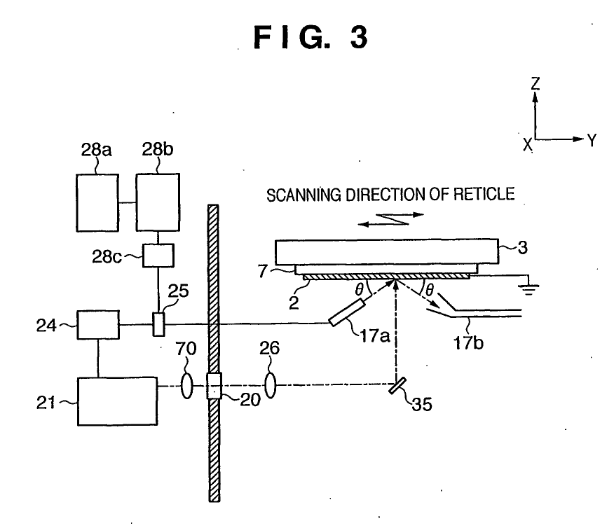

A particle removal mechanism according to this embodiment will be explained in detail with reference to FIG. 3.

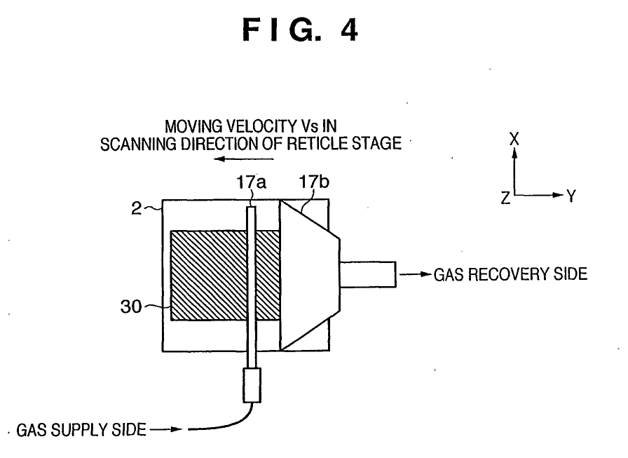

FIG. 3 is a partially enlarged view for explaining details of a gas blowing unit, laser irradiation unit, and recovery unit to attain the above-described particle removal actions. FIG. 4 is a view showing the positional relationship between a gas supply nozzle and a recovery nozzle when the units shown in FIG. 3 are seen from the reticle pattern surface side.

The laser irradiation unit will be explained in detail first. Reference numeral 21 denotes a pulse laser source. The pulse laser source 21 uses, e.g., an ArF laser (wavelength: 193 nm), a KrF laser (wavelength: 248 nm), or a YAG laser (wavelength: 266 nm or the like). Reference numeral 70 denotes a homogenizer for uniforming the irradiation distribution of a pulse beam emitted by the pulse laser source 21. Reference numeral 20 denotes a laser light guiding window made of an optical material such as a silica glass, which exhibits a low absorbance of the incident wavelength. The laser light supplied by the pulse laser source 21 is guided into the reticle stage space 4a via the laser light guiding window 20. Reference numeral 26 denotes an optical system for conversing and enlarging the laser light, which is guided from the laser light guiding window 20 into the reticle stage space 4a, to have a beam shape suitable to remove particles. Reference numeral 35 denotes a variable angle reflecting mirror. The laser light reflected by the reflecting mirror 35 strikes a pattern surface 30 of the reticle 2. The laser irradiation unit includes the pulse laser source 21, homogenizer 70, laser light guiding window 20, optical system 26, and reflecting mirror 35.

The gas blowing unit will be explained. Reference numeral 17a denotes a gas jet nozzle (supply nozzle). Reference numeral 28a denotes a gas source for a gas jet. Examples of the gas to be supplied are inert gasses such as Ar, N₂, Kr, and Xe gasses. Reference numeral 28b denotes a buffer chamber. The buffer chamber 28b is capable of gas flow control, and also functions as a cooling unit which cools a gas in advance to the degree that it condenses into fine particles upon adiabatic expansion. Reference numeral 28c denotes a flow control unit including, e.g., a metering valve and mass flow controller having a function which allows flow control. Reference numeral 25 denotes a solenoid valve for turning on/off gas supply to the supply nozzle 17a. The gas blowing unit includes the supply nozzle 17a, gas source 28a, buffer chamber 28b, flow control unit 28c, and solenoid valve 25.

As the gas reaches the supply nozzle 17a from the buffer chamber 28b via the flow control unit 28c and solenoid valve 25, the supply nozzle 17a blows it into a vacuum. At this time, since the pressure ratio between the gas supply side and the vacuum chamber side is equal to or higher than 0.528, the gas velocity at the outlet port of the nozzle is equal to or higher than the sound velocity, thus generating a stream which produces a shock wave. At the same time, the temperature rapidly drops upon rapid adiabatic expansion, and the gas condenses into fine particles in accordance with the above-described mechanism.

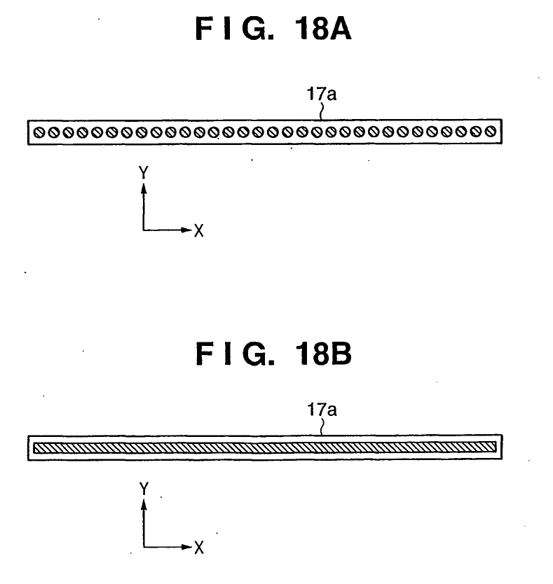

To blow a gas jet onto the entire reticle pattern surface 30, the supply nozzle 17a has a large number of orifices (gas supply port) formed to align themselves in one direction (the X direction) as shown in FIG. 18A. The gas supply port is not limited to the form shown in FIG. 18A, and the supply nozzle 17a may have only one orifice as shown in FIG. 18B as long as the entire gas supply port extends in one direction.

The position at which the blown gas jet impinges on the reticle 2 overlaps the pulse laser irradiation position. The distance between the supply nozzle 17a and the reticle 2 is optimized to maximize the removal efficiency, and is normally set at several mm.

Reference numeral 17b denotes a recovery nozzle (recovery unit) having a recovery port for recovering removed particles or efficiently exhausting a jet stream. The recovery nozzle 17b is bent into a funnel shape, as shown in FIG. 3. The angles of the supply nozzle 17a and recovery nozzle 17b are adjustable and are, e.g., about 45°.

In cleaning the reticle 2, the reticle stage 3 scan-moves the reticle 2 in a direction (the Y direction) perpendicular to the direction (the X direction) in which the gas supply port of the supply nozzle 17a extends. Then, the entire surface of the reticle 2 undergoes laser irradiation and gas blowing, thereby removing particles. Although the reticle 2 as a cleaning target moves in the Y direction here, its moving direction need not always be a direction perpendicular to the direction in which the gas supply port extends. If the moving direction of the target is different from the direction in which the gas supply port extends, wide-area cleaning is possible.

Referring to FIG. 4, since the gas jet flows from the supply nozzle 17a toward the recovery nozzle 17b, i.e., in the +Y direction, the stage driving direction is set in the −Y direction. This makes it possible to prevent any removed particles from adhering on the target again.

Reference numeral 24 denotes a pulse generator which can generate a pulse signal with a predetermined repetition frequency. This pulse signal triggers laser oscillation. Likewise, this pulse signal turns on/off the solenoid valve so that the supply nozzle 17a blows a gas jet in a pulse manner and the pulse laser oscillates in synchronism with it.

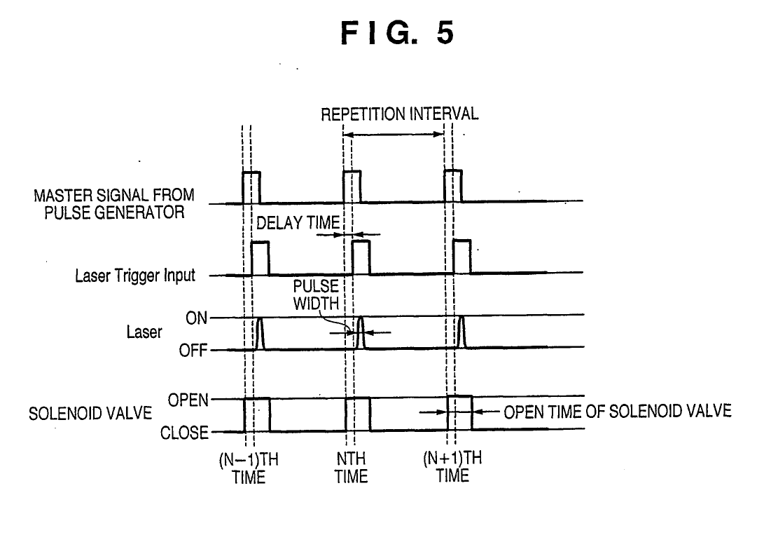

This sequence will be explained with reference to FIG. 5. As shown in FIG. 5, the pulse generator 24 generates pulse signals with predetermined repetition frequencies on the basis of a master signal. First, the solenoid valve 25 opens in synchronism with the leading edge of the master signal. Normally, since it takes several msec to activate the solenoid valve, it fully opens several msec after the leading edge of the master signal. On the other hand, the laser oscillation time (pulse width) is generally several nsec to several tens of nsec depending on the type of laser used. In view of this, a Laser Trigger Input signal is delayed from the master signal by a delay time of several msec or more to oscillate the laser after the solenoid valve 25 fully opens in advance. This makes it possible to delay the laser oscillation timing from the timing at which the solenoid valve 25 fully opens, thus allowing laser emission while blowing a gas jet.

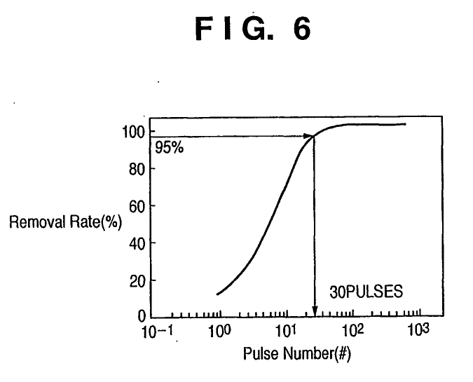

The relationship between the pulse beam irradiation count and the particle removal rate will be explained. An experiment concerning a pulse laser irradiation method conducted by the inventor of the present invention reveals that the removal rate of particles adhering on a substrate can be improved by irradiating it with a larger number of pulse beams. FIG. 6 shows the outline of this experiment. For example, when particles having a diameter of 0.1 μm are irradiated with one pulse under a specific laser irradiation condition, only about 10% of them is expected to be removed. However, as the pulse beam irradiation count increases, the removal rate gradually improves. In this example, when the particles are irradiated with about 80 pulses, nearly 100% of them is removed. In general, an adhesion force with which a particle adheres on a substrate is known to be mainly produced by the Van der Waals force, liquid cross-linking force, and electrostatic force. However, the Van der Waals force accounts for the adhesion force under a normal environment. The experimental result supposedly represents that irradiating the substrate with a large number of pulse beams gradually weakens an adhesion force with which a particle adheres on the substrate and then the particle is removed. According to another report, the magnitude of damage to a surface upon pulse laser irradiation does not depend on the integrated value of pulse energy but depends on the energy density per pulse. This fact is consistent with the result of the experiment conducted by the inventor of the present invention.

Although the relationship between the pulse beam irradiation count and the removal rate has been exemplified above, the same applies to that between the pulse jet blowing count and the removal rate.

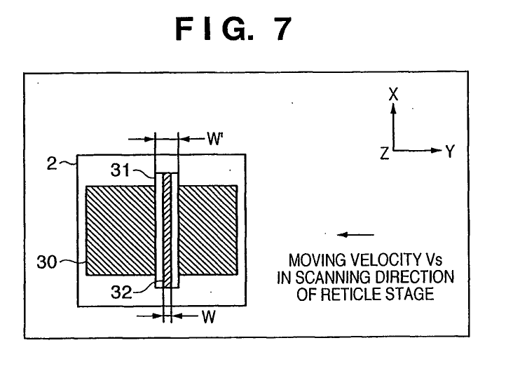

The laser irradiation position and gas blowing position on the reticle pattern surface will be explained. FIG. 7 shows the positional relationship when seen from the side of the reticle pattern surface 30. Reference numeral 32 indicates the laser light irradiation position; and 31, the position at which a gas jet impinges on the reticle 2. The entire surface of the reticle 2 is cleaned by laser irradiation and gas blowing while moving the reticle stage 3 in the −Y direction of FIG. 7 at the moving velocity Vs. In this way, the laser irradiation position and gas blowing position are overlapped to enhance the particle removal effect.

The relationship among a desired removal rate, stage velocity, and laser setting parameter will be explained. Referring to FIG. 7, let Vs [m/s] be the constant moving velocity of a cleaning target (reticle 2) during cleaning; W [m], the beam sheet thickness (the irradiation width on the reticle 2 in the scanning direction) of the pulse laser; F [Hz], the repetition frequency of the pulse laser; and N [#], the pulse laser irradiation count required for removal. Then, a time ΔTs taken to move the reticle 2 by the beam thickness W is given by:

ΔTs=W/Vs (1)

Assuming that an irradiation area in which the reticle moves within this time requires at least N times of pulse irradiation, a pulse time interval ΔTp is given by:

ΔTp=ΔTs/N=W/(Vs×N) (2)

A pulse time interval Δτ of the pulse laser source is given by:

Δτ=1/F (3)

Since ΔTp must be larger than Δτ to form a desired cleaning system, we have:

W/(Vs×N)>1/F (4)

which is rewritten into:

(Vs×N)/W<F (5)

That is, to obtain a desired removal rate (corresponding to N pulse irradiation), simple relational expression (5) must hold. For example, if Vs=100 [mm/s], F=300 [Hz], and N=30 [#], the required sheet beam thickness W is found to be equal to or larger than 10 [mm] from relational expression (5).

Although pulse laser irradiation has been exemplified above, just the same applies to gas blowing. More specifically, the above-described relational expression (5) naturally holds even when the sheet beam thickness W is changed to a width (a width at which a gas jet in the scanning direction impinges on the reticle 2) W′ of a gas jet on the reticle 2, and the number N of pulses required for pulse laser removal is changed to a number N′ of pulses required for gas jet removal. In exactly the same way, relational expression (5) holds even when a pulse laser and pulse jet are used simultaneously.

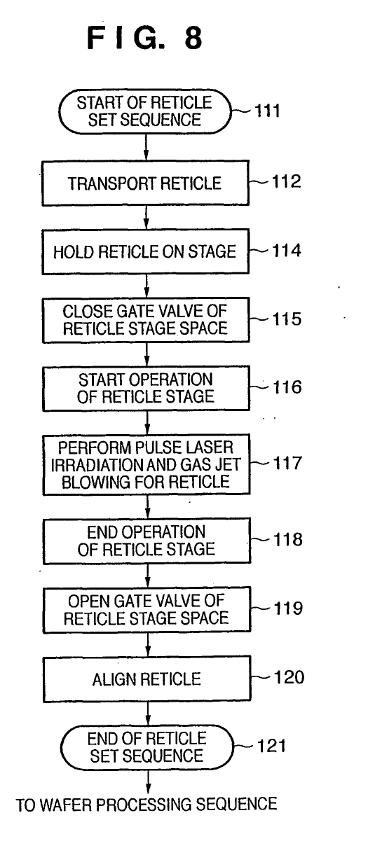

A sequence for cleaning the reticle 2 in this embodiment will be explained next with reference to FIG. 8. A case in which cleaning is performed immediately after transporting the reticle 2 onto the reticle stage 3 will be exemplified here.

In step 111, a reticle set sequence starts. In step 112, the reticle 2 is transported from a stocker in the reticle exchange room 19 into the reticle stage space 4a via the reticle load lock chamber 23. In step 114, the reticle 2 is held on the reticle stage 3 via the reticle chuck 7. In step 115, the gate valve 16a temporarily closes to prevent any gas and removed particles from flowing in the projection optical system space 4b upon cleaning. In step 116, the reticle 2 held on the reticle stage 3 starts moving to undergo cleaning. In step 117, laser irradiation and gas jet blowing for the reticle 2 are performed synchronously or independently. After completing pulse laser irradiation and gas jet blowing for the entire reticle pattern region, the operation of the reticle stage 3 ends in step 118. The gate valve 16a opens again in step 119, and the reticle 2 is aligned in step 120. In step 121, the reticle set sequence ends.

An example of a sequence in which particles readily adhere on the reticle is a transportation sequence. As illustrated in the sequence of FIG. 8, even particles which have adhered on the reticle upon reticle transportation can be removed by performing reticle cleaning immediately after the transportation.

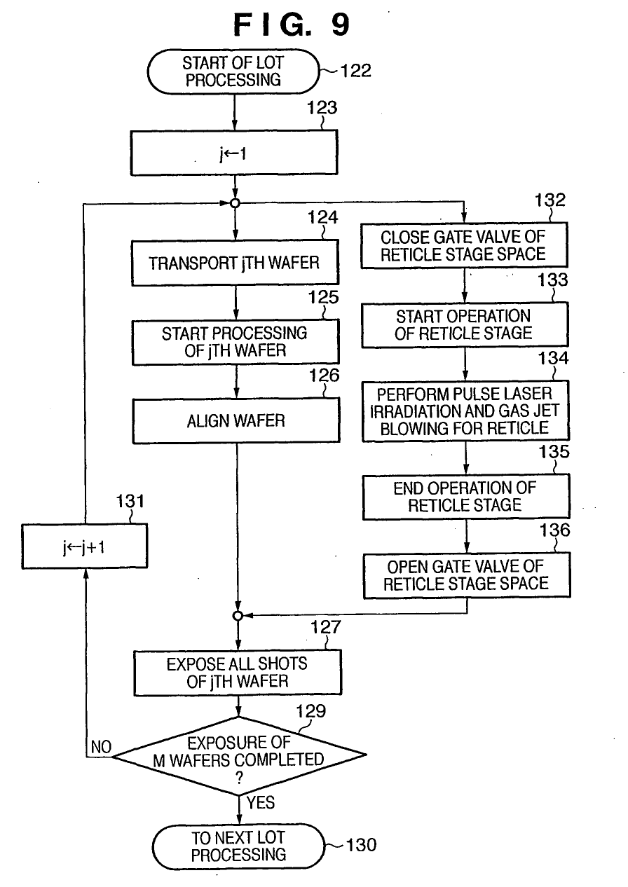

A case in which reticle cleaning is performed during wafer alignment in an exposure operation sequence will be exemplified with reference to FIG. 9. Referring to FIG. 9, the reticle is irradiated with a pulse laser at the wafer transportation operation timing and alignment operation timing.

In step 122, lot processing starts after the reticle 2 is loaded on the exposure apparatus and reticle alignment is completed, in order to expose a desired layer. In step 123, an argument j indicating the wafer number is set to 1. In step 124, the first wafer 1 is loaded on the wafer stage 27. In step 125, the processing of the first wafer starts. In step 126, the wafer 1 undergoes alignment measurement prior to exposure.

A reticle cleaning sequence starts parallel to steps 124, 125, and 126. In step 132, the gate valve 16a temporarily closes to prevent any gas and particles from flowing in the projection optical system space 4b upon cleaning. In step 133, the reticle 2 held on the reticle stage 3 starts moving to undergo cleaning. In step 134, laser irradiation and gas jet blowing for the reticle 2 are performed synchronously or independently. After completing pulse laser irradiation and gas jet blowing for the entire reticle pattern region, the operation of the reticle stage 3 ends in step 135. In step 136, the gate valve 16a opens again and the cleaning sequence ends. The series of cleaning sequence operations need only be completed within a period during which the wafer 1 is transported and aligned.

After completing the exposure of all shots, the processing of the first wafer is thoroughly complete. Since only one wafer is exposed at this point, the determination result in step 129 is No and the wafer number argument j is incremented in step 131. In step 124, a wafer is loaded on the wafer stage 27 again to process it as the second wafer. In step 125, the processing of the second wafer starts. As described above, a series of reticle cleaning operations in steps 132, 133, 134, 135, and 136 is performed parallel to steps 124, 125, and 126. By repeating the above-described operations, the series of exposure operations is completed for all of M wafers in step 129. In step 130, the processing shifts to the next lot processing.

In this example, the reticle is cleaned parallel to wafer exchange and alignment. This makes it possible to always keep the reticle clean without lowering the throughput. Although reticle cleaning is performed for each wafer in this example, it is possible to decrease the cleaning frequency depending on the use state of the exposure apparatus, as a matter of course.

In recent years, there is known an exposure apparatus which separately has an exposure stage and alignment stage. The reticle cleaning sequence described in this embodiment is applicable to even an exposure apparatus of this type.

### Second Embodiment

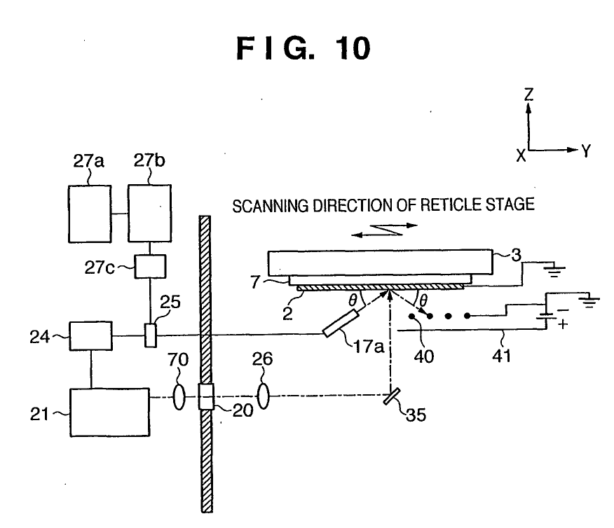

The second embodiment will be described with reference to FIG. 10. In the first embodiment, the particle and gas recovery unit uses a funnel-shaped recovery nozzle. The second embodiment will exemplify a case in which collecting mesh electrodes 40 and collecting plate 41 are formed near a reticle pattern surface as the recovery unit. An electric field is generated between the mesh electrodes 40 and the collecting plate 41 to collect particles using the electrostatic force. This arrangement can prevent any removed particles from adhering on the reticle again and scattering to other members.

An electric field must be generated between the mesh electrodes 40 and the collecting plate 41, whereas the one must not be generated between the surface of a reticle 2 and the mesh electrodes 40 by connecting (grounding) them to the GND potential. That is, removed particles enter into the mesh electrodes 40 at an angle of about θ shown in FIG. 10, together with a gas stream. The particles having passed through the mesh electrodes 40 are collected between the mesh electrodes 40 and the collecting plate 41 in accordance with an electrostatic force produced by the potential gradient between the mesh electrodes 40 and the collecting plate 41.

If there is a potential gradient between the reticle 2 and the mesh electrodes 40, a particle may adhere on the reticle 2 again depending on its polarity. To avoid this situation, the reticle surface and the mesh electrodes 40 are maintained at the same potential to prevent any particles from adhering on the reticle 2 again, as described above.

In general, fine particles produced upon a relatively rapid reaction are often electrically charged, whereas the ones produced upon a relatively slow reaction are often not electrically charged. From this viewpoint, even particles removed by a laser are electrically charged to some extent. In general, fine particles made of nonmetal materials or nonmetal oxides are positively charged, whereas the ones made of metals or metal oxides are negatively charged. For this reason, as in this embodiment, generating an electric field between the mesh electrodes 40 and the collecting plate 41 allows one of two electrodes to collect the particles even when they are made of materials having different electrification polarities.

Assume that the particles are not electrically charged. If they are conductors, their surfaces are electrically charged upon electrostatic induction by applying an electric field to them. Likewise, if they are nonconductors, their surfaces are electrically charged upon dielectric polarization. Collection becomes possible by forming a nonuniform electric field having a nonuniform electric field gradient. In this embodiment, even uncharged particles can be collected because a nonuniform electric field is formed.

Since electrodes can be easily introduced in a system design even though a recovery nozzle as explained in the first embodiment cannot be physically introduced in the design, the second embodiment has a higher versatility than the first embodiment.

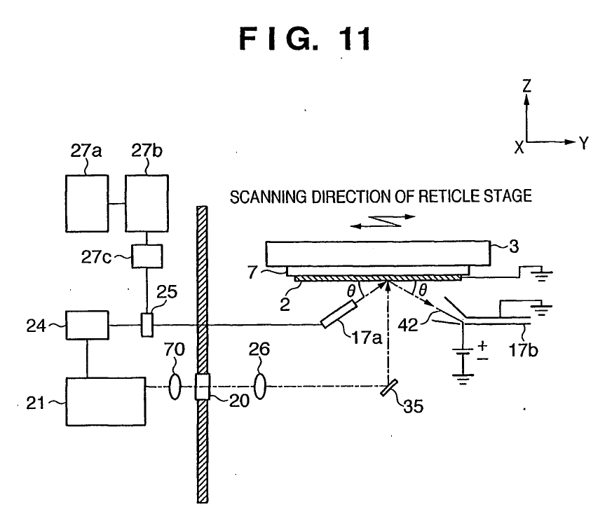

To collect removed particles using the electrostatic force, an electrode may be built in the recovery nozzle, as shown in FIG. 11. In this example, the recovery nozzle connects to the GND and incorporates a positive electrode. With this arrangement, an electric field exhibits a nonuniform strength in the nozzle and changes, so even uncharged particles removed are collected in the nozzle. The internal electrode can take various forms such as a mesh electrode and wire electrode, in addition to a familiar plate-like electrode.

### Third Embodiment

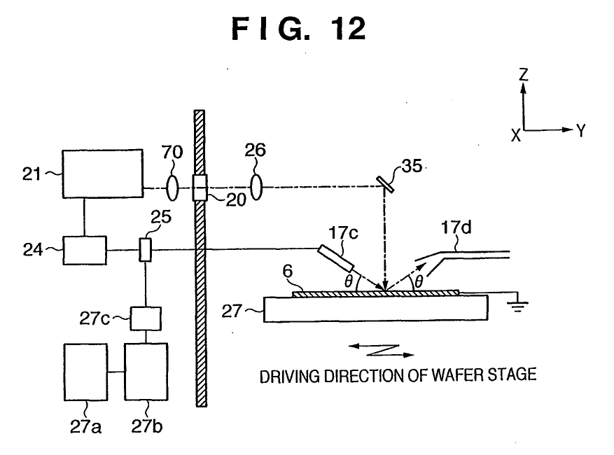

The third embodiment will be described with reference to FIG. 12. The third embodiment will exemplify a case in which the present invention is applied to the cleaning of a wafer chuck 6. Conventionally, most of particles adhering on the wafer chuck 6 are components of a photosensitive agent (photoresist) transferred upon adhering on the lower surface of the wafer. Another example of the particles is a deposit of dust particles floating in the atmosphere in which the apparatus is installed. When an EUV exposure apparatus is used, the exposure environment must be a vacuum environment, under which unwanted particles unique to it may adhere on a wafer chuck.

Referring to FIG. 12, reference numeral 17c denotes a jet nozzle (supply nozzle) for wafer chuck cleaning; and 17d, a particle and gas recovery nozzle. The distance between the supply nozzle 17c and the wafer chuck 6 is optimized to maximize the removal efficiency, and is normally set at several mm.

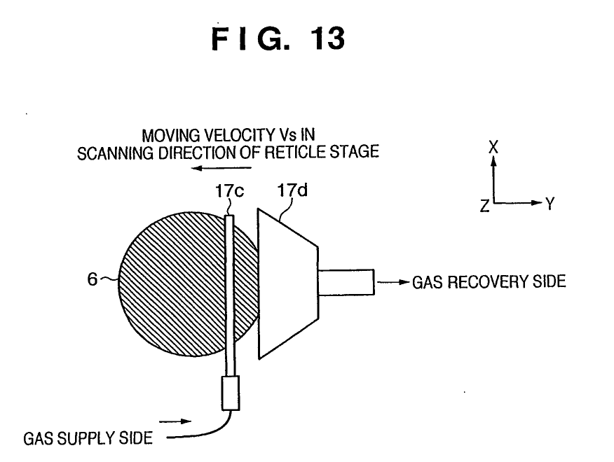

FIG. 13 shows the relative positional relationship among the wafer chuck 6 as a removal target, the supply nozzle 17c, and the recovery nozzle 17d. Referring to FIG. 13, a gas jet flows from the supply nozzle 17c toward the recovery nozzle 17d (in the +Y direction). It is therefore possible to prevent any particles from adhering on the wafer chuck 6 again by scanning a wafer stage 27 in the −Y direction.

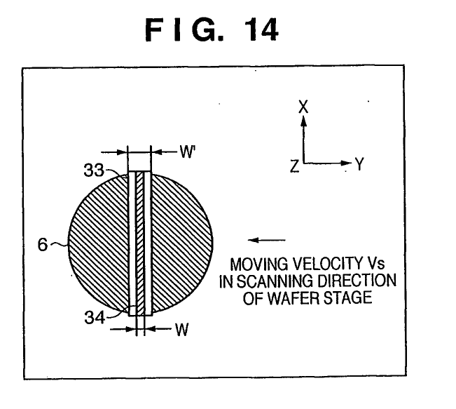

Referring to FIG. 14, reference numeral 33 indicates the laser irradiation position; and 34, the position at which a gas jet impinges on the wafer chuck 6. The entire surface of the wafer chuck 6 is cleaned by laser irradiation and gas blowing while moving the wafer stage 27 in the −Y direction of FIG. 13 at a moving velocity Vs. In this way, the laser irradiation position and gas blowing position are overlapped to enhance the particle removal effect.

Similar to the first embodiment, let Vs [m/s] be the constant moving velocity of the wafer stage 27; W [m], the beam sheet thickness of the pulse laser; and F [Hz], the repetition frequency of the pulse laser. Then; to obtain a desired removal rate (corresponding to N pulse irradiation), simple relational expression (5) must hold.

Although pulse laser irradiation has been exemplified above, just the same applies to gas blowing. Even when pulse laser irradiation and pulse jet blowing are used simultaneously, the above-described relational expression (5) naturally holds as long as the parameters are changed.

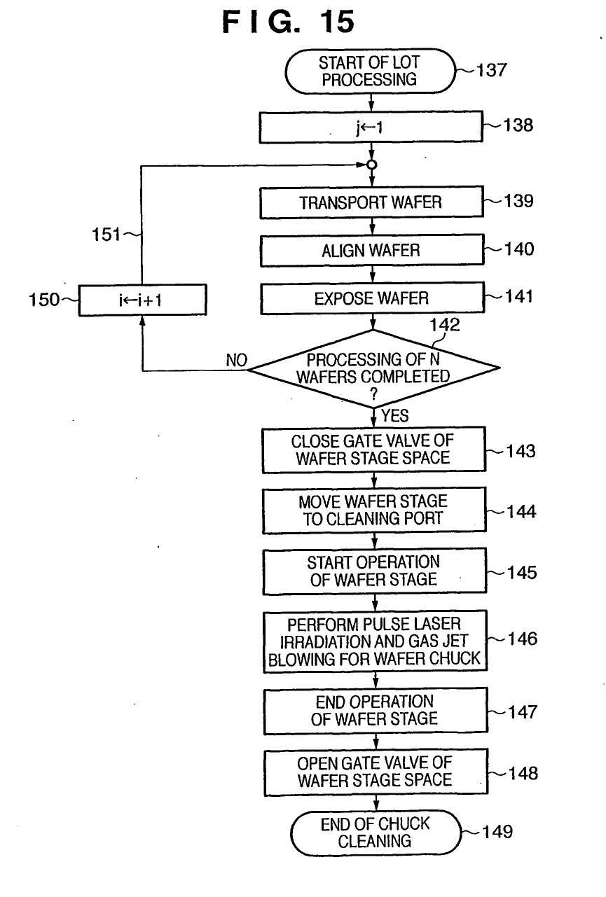

A sequence for cleaning the wafer stage 27 will be explained next with reference to the flowchart shown in FIG. 15.

In step 137, wafer processing starts. In step 138, an argument j indicating the wafer number is set to 1. In step 139, a wafer 1 is transported into the exposure apparatus. After an alignment operation in step 140, the circuit pattern of the reticle 2 is transferred onto the wafer 1 by exposure. Since only one wafer is exposed at this point, the determination result in step 142 is No and the wafer number argument j is incremented in step 150. The processing returns to step 139 to perform the series of exposure operations again. The above-described operations are repeated until the Nth wafer is processed. After that, the processing advances to a chuck cleaning operation. In step 143, a gate valve 16b closes to prevent any gas and particles from flowing in a projection optical system space 4b upon cleaning. In step 144, the wafer stage 27 moves to a wafer stage cleaning port (not shown). In step 145, an operation for cleaning the wafer stage 27 starts. In step 146, pulse laser irradiation and gas jet blowing for the wafer chuck 6 are performed synchronously or independently. After cleaning the entire surface of the wafer chuck 6, the operation of the wafer stage 27 ends in step 147. The gate valve 16b opens again in step 148, and the cleaning of the wafer chuck 6 ends in step 149.

Although the wafer chuck 6 is cleaned at the timing at which the Nth wafer is processed in this example, it can be cleaned occasionally.

Although the third embodiment has exemplified the method of cleaning the wafer chuck 6, just the same applies to a case in which the cleaning target is a reticle chuck, and a description thereof will not be made.

### Fourth Embodiment

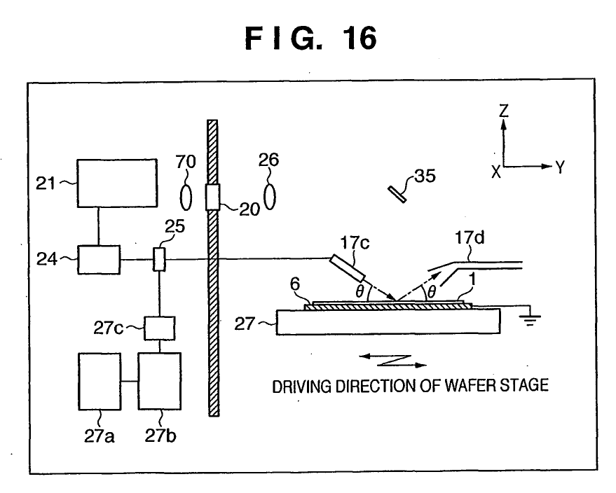

The fourth embodiment will be described with reference to FIG. 16. The fourth embodiment will exemplify a case in which the present invention is applied to the cleaning of a wafer 1. Particles adhering on the wafer 1 are supposed to be dust discharged from slidable units such as stages. Unwanted particles that are unique to an EUV exposure apparatus and are produced upon transporting the wafer 1 from the space under the air environment to the one under a vacuum environment are also taken into consideration.

Pulse laser irradiation is sometimes unsuitable to remove particles adhering on the wafer. This is because the wafer 1 is coated with a resist. When the wafer 1 is irradiated with a UV pulse laser light, the resist may often be exposed. In this case, only gas jet blowing can be used as the particle removal means. The arrangement shown in FIG. 16 is exactly the same as in wafer chuck cleaning, but does not adopt laser light irradiation.

The correlation between the laser irradiation position and the pulse jet blowing position is exactly the same as in the above-described case using a wafer chuck.

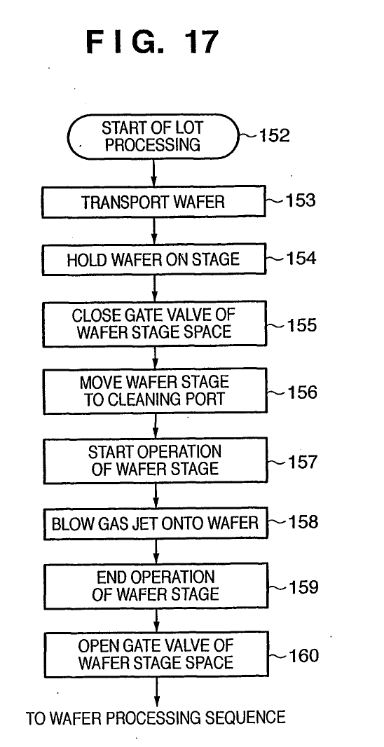

A sequence for cleaning the wafer 1 will be explained with reference to FIG. 17. A case in which cleaning is performed immediately after transporting the wafer to the stage will be exemplified here.

In step 152, wafer processing starts. In step 153, the wafer 1 is transported from a stocker in a wafer exchange room 14 into a wafer stage space 4c via a wafer load lock chamber 15. In step 154, the wafer 1 is held on a wafer stage 27 via a wafer chuck 6. In step 155, a gate valve 16b temporarily closes to prevent any gas and removed particles from flowing in a projection optical system space 4b upon cleaning. In step 156, the wafer stage 27 moves to a cleaning port. In step 157, the wafer 1 held on the wafer stage 27 starts moving by scanning to undergo cleaning. In step 158, a gas jet is blown onto the wafer surface. After completing gas jet blowing for the entire wafer surface, the operation of the wafer stage 27 ends in step 159. In step 160, the gate valve 16b opens again and the processing returns to a normal wafer processing sequence.

In this way, even particles which have adhered on the wafer upon wafer transportation can be removed by performing wafer cleaning immediately after the transportation.

### Fifth Embodiment

An embodiment of a method of manufacturing a semiconductor device using an EUV exposure apparatus described in each of the above-described embodiments will be explained next.

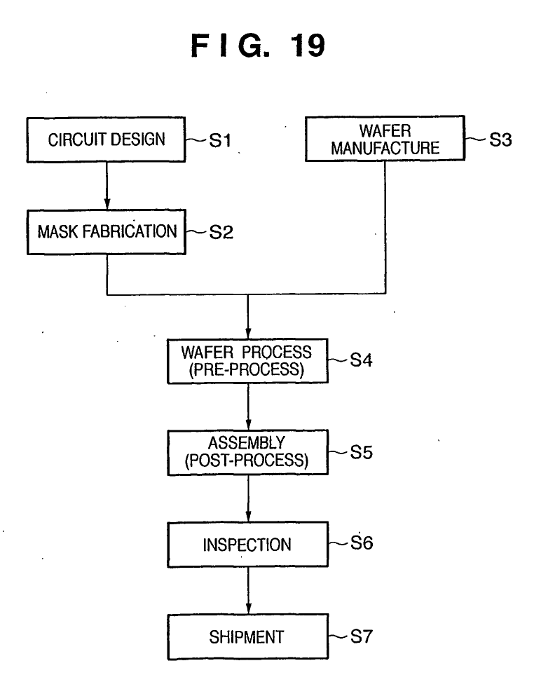

FIG. 19 shows the manufacturing sequence of a semiconductor device (a semiconductor chip such as an IC or LSI). In step S1 (circuit design), the circuit of a semiconductor device is designed. In step S2 (reticle fabrication), a mask (reticle 2) on which the designed circuit pattern is formed is fabricated. In step S3 (wafer manufacture), a wafer (wafer 1) is manufactured using a material such as silicon. In step S4 (wafer process) called a preprocess, an actual circuit is formed on the wafer by lithography using the prepared mask and wafer. In step S5 (assembly) called a post-process, a semiconductor chip is formed using the wafer manufactured in step S4. This step includes processes such as assembly (dicing and bonding) and packaging (chip encapsulation). In step S6 (inspection), inspections including operation check test and durability test of the semiconductor device manufactured in step S5 are performed. A semiconductor device is completed with these processes and shipped in step S7.

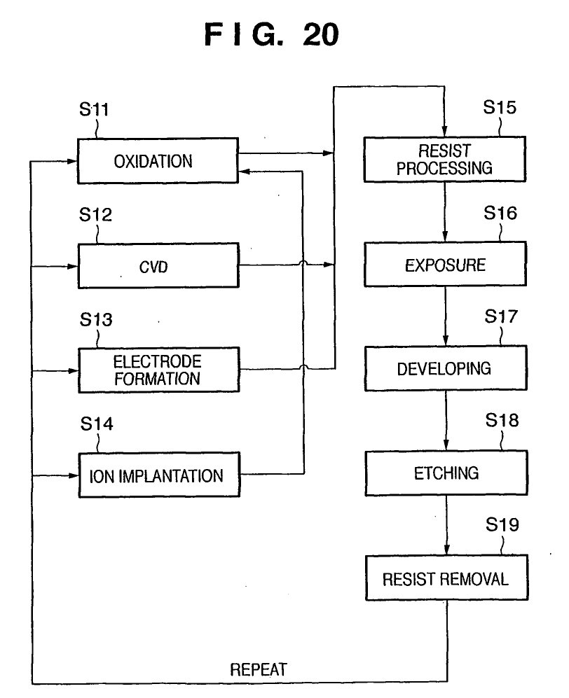

FIG. 20 shows the detailed sequence of the wafer process. In step S11 (oxidation), the surface of the wafer (wafer 1) is oxidized. In step S12 (CVD), an insulating film is formed on the wafer surface. In step S13 (electrode formation), an electrode is formed on the wafer by deposition. In step S14 (ion implantation), ions are implanted into the wafer. In step S15 (resist processing), a resist (photosensitive agent) is applied to the wafer. In step S16 (exposure), the above-described exposure apparatus transfers the circuit pattern image of the mask (reticle 2) onto the wafer by exposure. In step S17 (development), the exposed wafer is developed. In step S18 (etching), portions other than the developed resist are etched. In step S19 (resist removal), any unnecessary resist remaining after etching is removed. By repeating these steps, a multilayered structure of circuit patterns is formed on the wafer.

When the manufacturing method according to this embodiment is used, a semiconductor device with high degree of integration, which is conventionally difficult to manufacture, can be manufactured.

According to the present invention, it is possible to satisfactorily suppress any particles from adhering on an object without significantly decreasing the throughput and apparatus operation rate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-332172, filed on Dec. 8, 2006, which is hereby incorporated by reference herein in its entirety.

1. An exposure apparatus for exposing a substrate to radiant energy in a vacuum, said apparatus comprising:
a chamber in which the vacuum is generated;
a blowing device including a supply nozzle located in said chamber and configured to blow, through said supply nozzle, a gas to an object arranged in said chamber in which the vacuum is generated; and
a recovery device including a recovery nozzle located in said chamber and configured to recover, through said recovery nozzle, the gas blown into said chamber through said supply nozzle,
wherein said apparatus is configured so that the object moves in a direction opposite to a direction from said supply nozzle to said recovery nozzle, parallel to blowing by said blowing device.

2. An exposure apparatus for exposing a substrate to radiant energy in a vacuum, said apparatus comprising:
a chamber in which the vacuum is generated;
a blowing device including a supply nozzle located in said chamber and configured to blow, through said supply nozzle, a gas to an object arranged in said chamber in which the vacuum is generated;
a recovery device including a recovery nozzle located in said chamber and configured to recover, through said recovery nozzle, the gas blown into said chamber through said supply nozzle; and
an irradiator configured to irradiate the object with a pulse laser light,
wherein said apparatus is configured so that a region on the object, to which said blowing device blows the gas, overlaps a region on the object, which is irradiated with the pulse laser light, and gas blowing by said blowing device and pulse laser light irradiation by said irradiator are performed in synchronism with each other.

3. An exposure apparatus for exposing a substrate to radiant energy in a vacuum, said apparatus comprising:
a chamber in which the vacuum is generated;
a blowing device including a supply nozzle located in said chamber and configured to blow, through said supply nozzle, a gas to an object arranged in said chamber in which the vacuum is generated; and
a recovery device including a recovery nozzle located in said chamber, and recovers, through said recovery nozzle, the gas blown into said chamber through said supply nozzle,
wherein said apparatus is configured so that said blowing device blows a supersonic gas with a shock wave.

4. An exposure apparatus for exposing a substrate to radiant energy in a vacuum, said apparatus comprising:
a chamber in which the vacuum is generated;
a blowing device including a supply nozzle located in said chamber and configured to blow, through said supply nozzle, a gas to an object arranged in said chamber in which the vacuum is generated; and
a recovery device including a recovery nozzle located in said chamber and configured to recover, through said recovery nozzle, the gas blown into said chamber through said supply nozzle,
wherein said apparatus is configured so that a component of the gas blown by said blowing device is sublimated to a solid.

5. An apparatus according to claim 1, wherein a supply port of said supply nozzle extends in one direction.

6. An apparatus according to claim 1, wherein said recovery device includes a grounded electrode and one of a positive electrode and a negative electrode, and the object is grounded.

7. An apparatus according to claim 1, wherein the object includes one of the substrate, a substrate chuck, a reticle, and a reticle chuck.

8. A method of manufacturing a device, said method comprising:
exposing a substrate to radiant energy using an exposure apparatus defined in claim 1;
developing the exposed substrate; and
processing the developed substrate to manufacture the device.
